(19) United States
(12) Patent Application Publication
(10) Pub. No.: US 2026/0245634 A1
(43) Pub. Date: Aug. 20, 2026

(54) CURRENT PROFILE BALANCING FOR FLASH MEMORY

(71) Applicant: Silicon Storage Technology, Inc., San Jose, CA (US)

(72) Inventors: Hieu Van TRAN, San Jose, CA (US); Kyle MCMARTIN, San Jose, CA (US); Hyun Bai KIM, San Jose, CA (US); Anh LY, San Jose, CA (US); Kha NGUYEN, Saigon Hi-Tech Park (VN); Hien PHAM, Saigon Hi-Tech Park (VN)

(73) Assignee: Silicon Storage Technology, Inc., San Jose, CA (US)

(21) Appl. No.: 19/206,940

(22) Filed: May 13, 2025

Related U.S. Application Data
(60) Provisional application No. 63/760,061, filed on Feb. 18, 2025.

(51) Int. Cl. G11C 16/30; G11C 16/08; G11C 29/00

(52) U.S. Cl. CPC G11C 16/30; G11C 16/08; G11C 29/848

(57) ABSTRACT

In one example, a method comprises precharging at least one input to or output from a memory array to a supply voltage; performing at least one operation by the memory array requiring the precharged at least one input to or output from the memory array to have a voltage lower than the supply voltage; and discharging the precharged at least one input to or output from the memory array to the voltage lower than the supply voltage in response to the at least one operation.

### PRIORITY CLAIM

This application claims priority to U.S. Provisional Patent Application No. 63/760,061, titled “Current Profile Balancing for Flash Memory,” and filed on Feb. 18, 2025, which is incorporated by reference herein.

### FIELD OF THE INVENTION

Numerous examples are disclosed of systems and methods for performing current profile balancing for flash memory.

### BACKGROUND OF THE INVENTION

Non-volatile memories are well known. For example, U.S. Pat. No. 5,029,130 (“the '130 patent”), which is incorporated herein by reference, discloses an array of split gate non-volatile memory cells, which are a type of flash memory cells. Such a memory cell 110 is shown in FIG. 1. Each memory cell 110 includes source region 14 and drain region 16 formed in semiconductor substrate 12, with channel region 18 there between. Floating gate 20 is formed over and insulated from (and controls the conductivity of) a first portion of the channel region 18, and over a portion of the source region 14. Word line terminal 22 (which is typically coupled to a word line) has a first portion that is disposed over and insulated from (and controls the conductivity of) a second portion of the channel region 18, and a second portion that extends up and over the floating gate 20. The floating gate 20 and word line terminal 22 are insulated from the substrate 12 by a gate oxide. Bitline 24 is coupled to drain region 16.

Memory cell 110 is erased (where electrons are removed from the floating gate) by placing a high positive voltage on the word line terminal 22, which causes electrons on the floating gate 20 to tunnel through the intermediate insulation from the floating gate 20 to the word line terminal 22 via Fowler-Nordheim (FN) tunneling.

Memory cell 110 is programmed by source side injection (SSI) with hot electrons (where electrons are placed on the floating gate) by placing a positive voltage on the word line terminal 22, and a positive voltage on the source region 14. Electron current will flow from the drain region 16 towards the source region 14. The electrons will accelerate and become energized when they reach the gap between the word line terminal 22 and the floating gate 20. Some of the heated electrons will be injected through the gate oxide onto the floating gate 20 due to the attractive electrostatic force from the floating gate 20.

Memory cell 110 is read by placing positive read voltages on the drain region 16 and word line terminal 22 (which turns on the portion of the channel region 18 under the word line terminal). If the floating gate 20 is positively charged (i.e., erased of electrons), then the portion of the channel region 18 under the floating gate 20 is turned on as well, and current will flow across the channel region 18, which is sensed as the erased or “1” state. If the floating gate 20 is negatively charged (i.e., programmed with electrons), then the portion of the channel region under the floating gate 20 is mostly or entirely turned off, and current will not flow (or there will be little flow) across the channel region 18, which is sensed as the programmed or “0” state.

Table No. 1 depicts typical voltage and current ranges that can be applied to the terminals of memory cell 110 for performing read, erase, and program operations:

TABLE NO. 1
Operation of Flash Memory Cell 110 of FIG. 1

| | | |
|---|---|---|
| WL | BL | SL |

| | | | | | | |
|---|---|---|---|---|---|---|
| Read | 2-3 | V | 0.6-2 | V | 0 | V |
| Erase | ~11-13 | V | 0 | V | 0 | V |
| Program | 1-2 | V | 10.5-3 | μA | 9-10 | V |

Other split gate memory cell configurations, which are other types of flash memory cells, are known. For example, FIG. 2 depicts a four-gate memory cell 210 comprising source region 14, drain region 16, floating gate 20 over a first portion of channel region 18, a select gate 22 (typically coupled to a word line, WL) over a second portion of the channel region 18, a control gate 28 over the floating gate 20, and an erase gate 30 over the source region 14. This configuration is described in U.S. Pat. No. 6,747,310, which is incorporated herein by reference for all purposes. Here, all gates are non-floating gates except floating gate 20, meaning that they are electrically connected or connectable to a voltage source. Programming is performed by heated electrons from the channel region 18 injecting themselves onto the floating gate 20. Erasing is performed by electrons tunneling from the floating gate 20 to the erase gate 30.

Table No. 2 depicts typical voltage and current ranges that can be applied to the terminals of memory cell 210 for performing read, erase, and program operations:

TABLE NO. 2
Operation of Flash Memory Cell 210 of FIG. 2

| | WL/SG | | BL | | CG | | EG | | SL | |
|---|---|---|---|---|---|---|---|---|---|---|
| Read | 1.0-2 | V | 0.6-2 | V | 0-2.6 | V | 0-2.6 | V | 0 | V |
| Erase | −0.5 V/0 V | | 0 | V | 0 V/−8 V | | 8-12 | V | 0 | V |
| Program | 1 | V | 0.1-1 | μA | 8-11 | V | 4.5-9 | V | 4.5-5 | V |

FIG. 3 depicts a three-gate memory cell 310, which is another type of flash memory cell. Memory cell 310 is identical to the memory cell 210 of FIG. 2 except that memory cell 310 does not have a separate control gate. The erase operation (whereby erasing occurs through use of the erase gate) and read operation are similar to that of the FIG. 2 except there is no control gate bias applied. The programming operation also is done without the control gate bias, and as a result, a higher voltage is applied on the source line during a program operation to compensate for a lack of control gate bias.

Table No. 3 depicts typical voltage and current ranges that can be applied to the terminals of memory cell 410 for performing read, erase, and program operations:

TABLE NO. 3
Operation of Flash Memory Cell 310 of FIG. 3

| | | | |
|---|---|---|---|
| WL/SG | BL | EG | SL |

| | | | | | | | | |
|---|---|---|---|---|---|---|---|---|
| Read | 0.7-2.2 | V | 0.6-2 | V | 0-2.6 | V | 0 | V |

| | | | | | | | |
|---|---|---|---|---|---|---|---|
| Erase | −0.5 V/0 V | 0 | V | 11.5 | V | 0 | V |

| | | | | | | | | |
|---|---|---|---|---|---|---|---|---|
| Program | 1 | V | 0.2-3 | μA | 4.5 | V | 7-9 | V |

FIG. 4 depicts stacked gate memory cell 410, which is another type of flash memory cell. Memory cell 410 is similar to memory cell 110 of FIG. 1, except that floating gate 20 extends over the entire channel region 18, and control gate 22 (which here will be coupled to a word line) extends over floating gate 20, separated by an insulating layer (not shown). The erase is done by FN tunneling of electrons from FG to substrate, programming is by channel hot electron (CHE) injection at region between the channel 18 and the drain region 16, by the electrons flowing from the source region 14 towards to drain region 16 and read operation which is similar to that for memory cell 110 with a higher control gate voltage.

Table No. 4 depicts typical voltage ranges that can be applied to the terminals of memory cell 410 and substrate 12 for performing read, erase, and program operations:

TABLE NO. 4
Operation of Flash Memory Cell 410 of FIG. 4

| | CG | | BL | | SL | Substrate |
|---|---|---|---|---|---|---|
| Read | 2-5 | V | 0.6-2 | V | 0 V | 0 V |
| Erase | −8 to −10 V/0 V | | FLT | | FLT | 8-10 V/15-20 V |
| Program | 8-12 | V | 3-5 | V | 0 V | 0 V |

The methods and means described herein may apply to other non-volatile memory technologies such as FINFET split gate flash or stack gate flash memory, NAND flash, SONOS (silicon-oxide-nitride-oxide-silicon, charge trap in nitride), MONOS (metal-oxide-nitride-oxide-silicon, metal charge trap in nitride), ReRAM (resistive ram), PCM (phase change memory), MRAM (magnetic ram), FeRAM (ferroelectric ram), CT (charge trap) memory, CN (carbon-tube) memory, OTP (bi-level or multi-level one time programmable), and CeRAM (correlated electron ram), without limitation.

FIG. 5 depicts array 500. The array 500 shows four bitlines (aka column, BL0/1/2/3) and four rows of memory cells as an example. Typically there is more than four columns and more than four rows for an memory array. A plurality of memory cells (e.g., cells 110, 210, 310, and/or 410) can be arranged in rows and columns to form a memory cell array, as illustrated in FIG. 5. Memory cell pairs can be placed end to end to form columns of memory cells (where adjacent memory cell pairs can share a common drain region). Each column can include a bit line (e.g., BL0, BL1, BL2, BL3, etc.) electrically connecting together all the drain regions in the column. Each row of memory cells can include a control gate line (e.g., CG0, CG1, CG2, CG3, etc.) electrically connecting together all the control gates in the row of memory cells. For example, all the control gates in each row of memory cells can be formed as a continuous line of conductive material, where a portion of the continuous line passing through any given memory cell serves as its control gate. Each row of memory cells can include a word gate line (e.g., WL0, WL1, WL2, WL3, etc.) electrically connecting together all the word gates in the row of memory cells. For example, all the word gates in each row of memory cells can be formed as a continuous line of conductive material, where a portion of the continuous line passing through any given memory cell serves as its word gate. Each row of memory cell pairs can include an erase gate line (e.g., EG0, EG1, etc.) electrically connecting together all the erase gates in the row of memory cell pairs. For example, all the erase gates in each row of memory cell pairs can be formed as a continuous line of conductive material, where a portion of the continuous line passing through any given memory cell serves as its erase gate. Each row of memory cell pairs can include a source line (e.g., SL0, SL1, etc.) electrically connecting together all the source regions in the row of memory cell pairs. For example, all the source regions in each row of memory cell pairs can be formed as a continuous line of conductive diffusion in the substrate, where a portion of the continuous line passing through any given memory cell serves as its source region.

In non-volatile memory, such as in the examples discussed above, current loading may exhibit very large current peaks in operation such as during read, program, or erase due to large load switching during some operations such as address switching, data switching, bitline precharging for read operations, charge pump generation, and other operations. These large current peaks can degrade performance, for example by causing large voltage drops from voltage regulators or by introducing large amounts of noise.

### SUMMARY OF THE INVENTION

Numerous examples are disclosed of systems and methods for performing current profile balancing for flash memory.

In one example, a method comprises precharging at least one input to or output from a memory array to a supply voltage; performing at least one operation by the memory array requiring the precharged at least one input to or output from the memory array to have a voltage lower than the supply voltage; and discharging the precharged at least one input to or output from the memory array to the voltage lower than the supply voltage in response to the at least one operation.

In another example, a method comprises performing an operation on a memory array, wherein the operation is performed by: sending first signals to a first plurality of inputs to or outputs from the memory array forming a first group, and after sending the first signals, sending second signals to a second plurality of inputs to or outputs from the memory array forming a second group different from the first group; wherein each of the first signals and second signals are required to complete the operation.

In another example, a system comprises an array comprising non-volatile memory cells arranged into rows and columns; and an addressing block to address the rows and columns by a binary address sequence having all addresses differ from adjacent addresses in the sequence by fewer than a maximum number of binary bits in the addresses.

In another example, a method comprises comparing, by a first address cluster, a first subset of a plurality of address bits with at least one known bad address of a memory array; in response to a true result of the comparing by the first address cluster, comparing, by a second address cluster, a second subset of the plurality of address bits with the at least one known bad address of the memory array; in response to a true result of the comparing by the second address cluster, storing incoming data in an address of the memory array other than the at least one known bad address.

In another example, a system comprises an array of non-volatile memory cells arranged in rows and columns; and a cluster comparison circuit comprising a plurality of address clusters each configured to compare a respective subset of address bits against a respective portion of at least one known bad address of the memory array; wherein in response to each of the plurality of address clusters returning a true result, the array is configured to address the non-volatile memory cells at an address different from an address indicated by the address bits.

In another example, a method comprises performing a staggered precharging of a plurality of data lines for a plurality of memory cells, the staggered precharging comprising: precharging a first group of the data lines at a first time, and precharging a second group of the data lines at a second time after the first time; and sensing data stored in the plurality of memory cells having the precharged data lines.

In another example, a system comprises an array of non-volatile memory cells arranged in rows and columns; a plurality of sensing circuits, wherein each of the columns of memory cells in the array is coupled to one of the plurality of sensing circuits; and a controller for pre-charging the plurality of sensing circuits in a staggered sequence.

### BRIEF DESCRIPTION OF THE DRAWINGS

FIG. 1 depicts a prior art split gate flash memory cell.

FIG. 2 depicts another prior art split gate flash memory cell.

FIG. 3 depicts another prior art split gate flash memory cell.

FIG. 4 depicts another prior art stacked gate flash memory cell.

FIG. 5 depicts an example of an array of flash memory cells.

FIG. 6 depicts an example of a system.

FIG. 7 depicts a system coupled to a serial interface.

FIG. 8A depicts a system comprising a memory array.

FIG. 8B depicts a system comprising a plurality of memory arrays.

FIG. 8C depicts a system comprising a plurality of memory arrays.

FIG. 9 depicts an example of a memory system.

FIG. 10 depicts an example of a memory system comprising precharge circuits.

FIG. 11A depicts an example of a system input or output.

FIG. 11B depicts another example of a system input.

FIG. 12A depicts an example system timing diagram.

FIG. 12B depicts another example system timing diagram.

FIG. 13 depicts an example asymmetrical circuit staggering for a system.

FIG. 14A depicts an example asymmetrical circuit staggering timing diagram.

FIG. 14B depicts details of an example asymmetrical circuit staggering timing diagram.

FIG. 15 depicts an example sensing circuit for a system.

FIG. 16 depicts an example asymmetrical load staggering for a system.

FIG. 17 depicts an example set of redundancy repair clusters.

### DETAILED DESCRIPTION OF THE INVENTION

### System Architecture

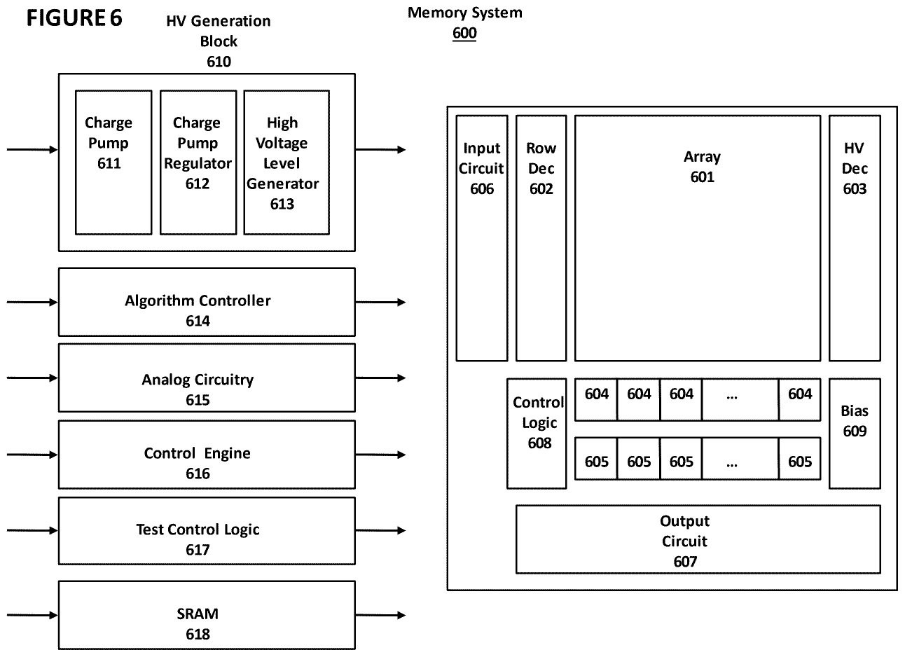

FIG. 6 depicts a block diagram of system 600. System 600 comprises memory array 601, row decoder 602, high voltage decoder 603, column decoders 604, bit line drivers 605 (such as bit line control circuitry for programming), input circuit 606, output circuit 607, control logic 608, and bias generator 609. System 600 further comprises high voltage generation block 610, which comprises charge pump 611, charge pump regulator 612, and high voltage level generator 613. System 600 further comprises (program/erase, or weight tuning) algorithm controller 614, analog circuitry 615, control engine 616 (that may include functions such as arithmetic functions, activation functions, embedded microcontroller logic, without limitation), test control logic 617, and static random access memory (SRAM) block 618 to store intermediate data such as for input circuits (e.g., activation data) or output circuits (neuron output data, partial sum output neuron data) or data in for programming (such as data in for a whole row or for multiple rows).

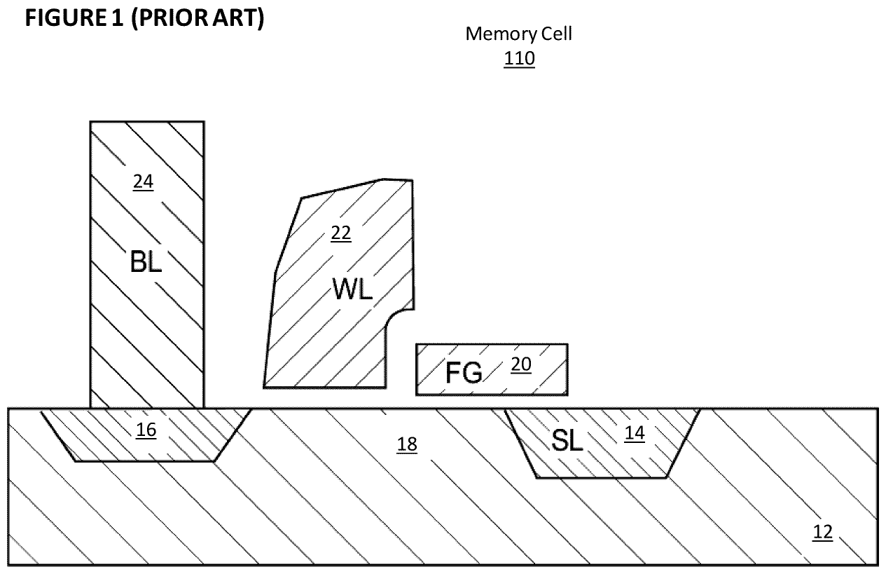

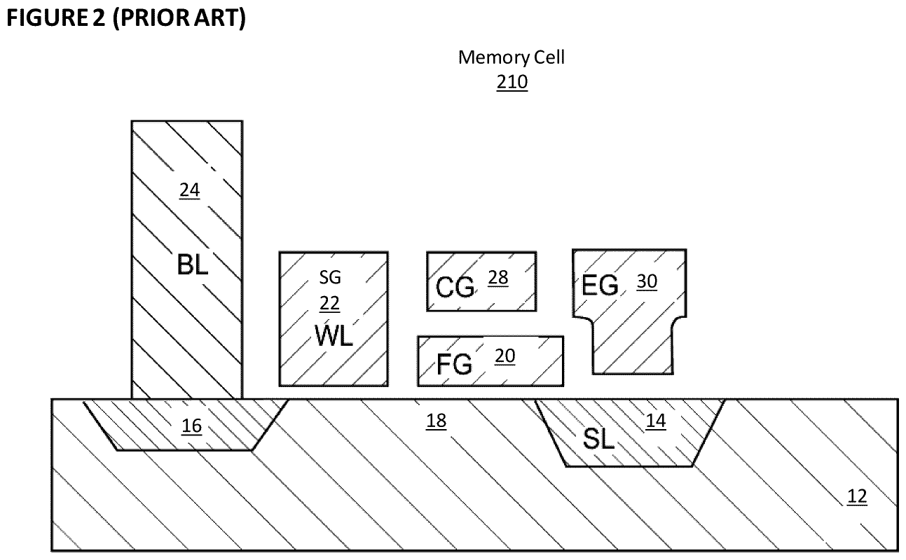

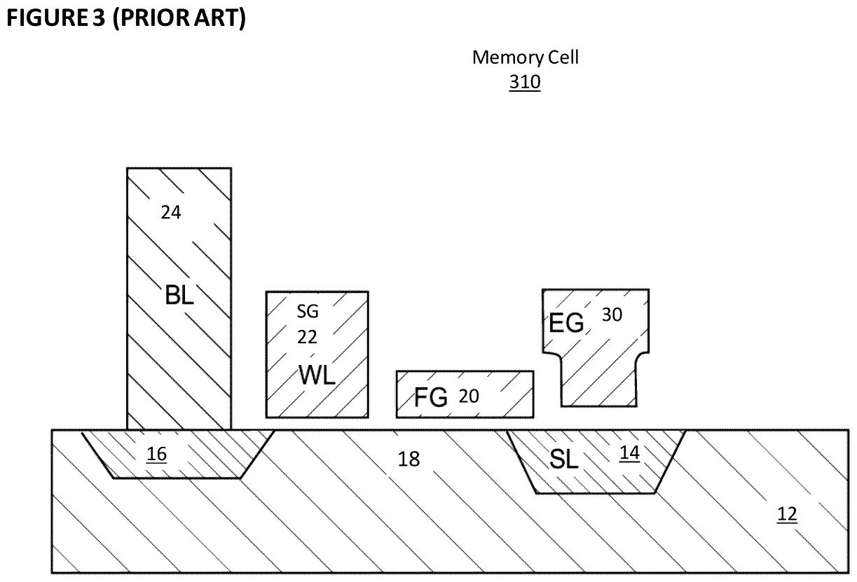

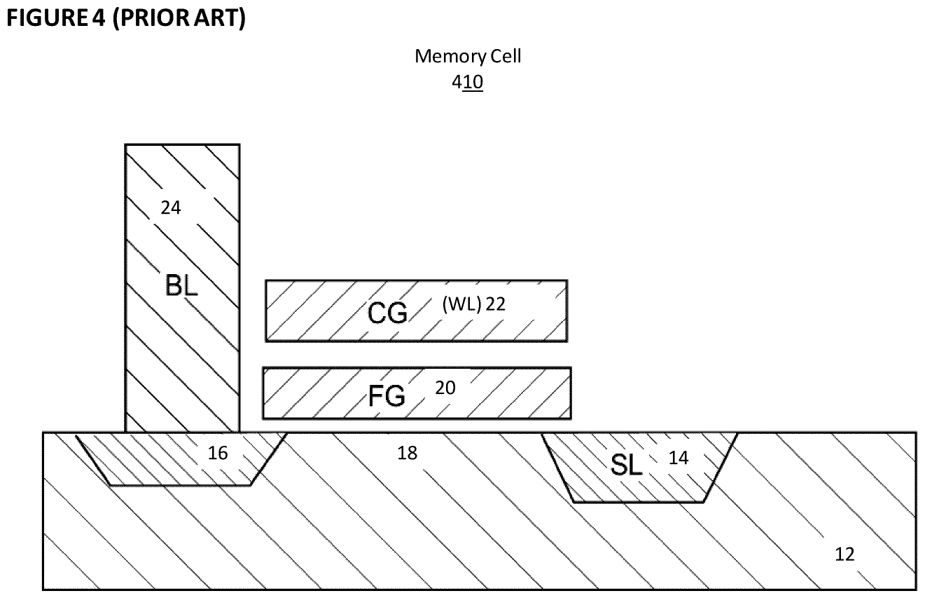

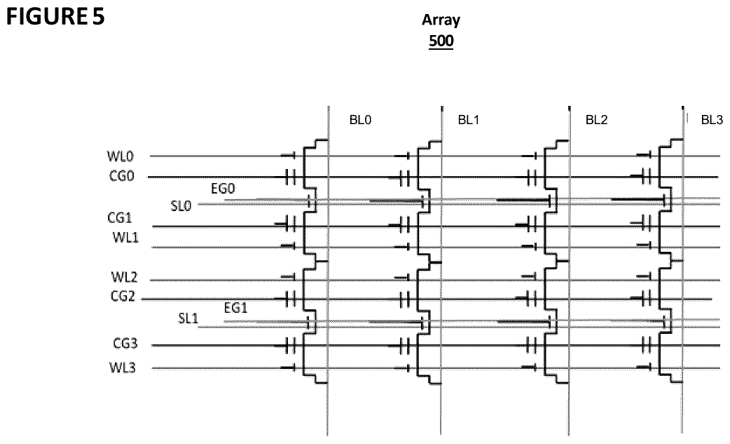

Array 601 comprises an array of non-volatile memory cells arranges in rows and columns. In one example, the memory cells of array 601 comprise split-gate flash memory cells such as cells based on the design of memory cell 110, 210, or 310 in FIGS. 1, 2, and 3, respectively. In another example, the memory cells of array 601 comprise stacked-gate flash memory cells such as cells based on the design of memory cell 410 in FIG. 4.

The input circuit 606 may include circuits such as a DAC (digital to analog converter), DPC (digital to pulses converter, digital to time modulated pulse converter), AAC (analog to analog converter, such as a current to voltage converter, logarithmic converter), PAC (pulse to analog level converter), or any other type of converters. The input circuit 606 may implement one or more of normalization, linear or non-linear up/down scaling functions, or arithmetic functions. The input circuit 606 may implement a temperature compensation function for input levels. The input circuit 606 may implement an activation function such as ReLU or sigmoid. Input circuit 606 may store digital activation data to be applied as, or combined with, an input signal during a program or read operation. The digital activation data can be stored in registers. Input circuit 606 may comprise circuits to drive the array terminals, such as CG, WL, EG, and SL lines, which may include sample-and-hold circuits and buffers. A DAC can be used to convert digital activation data into an analog input voltage to be applied to the array.

The output circuit 607 may include circuits such as an ITV (current-to-voltage circuit), ADC (analog to digital converter, to convert neuron analog output to digital bits), AAC (analog to analog converter, such as a current to voltage converter, logarithmic converter), APC (analog to pulse(s) converter, analog to time modulated pulse converter), or any other type of converters. The output circuit 607 may convert array outputs into activation data. The output circuit 607 may implement an activation function such as rectified linear activation function (ReLU) or sigmoid. The output circuit 607 may implement one or more of statistic normalization, regularization, up/down scaling/gain functions, statistical rounding, or arithmetic functions (e.g., add, subtract, divide, multiply, shift, log) for neuron outputs. The output circuit 607 may implement a temperature compensation function for neuron outputs or array outputs (such as bitline output) so as to keep power consumption of the array approximately constant or to improve precision of the array (neuron) outputs such as by keeping the IV slope approximately the same over temperature. The output circuit 607 may comprise registers for storing output data.

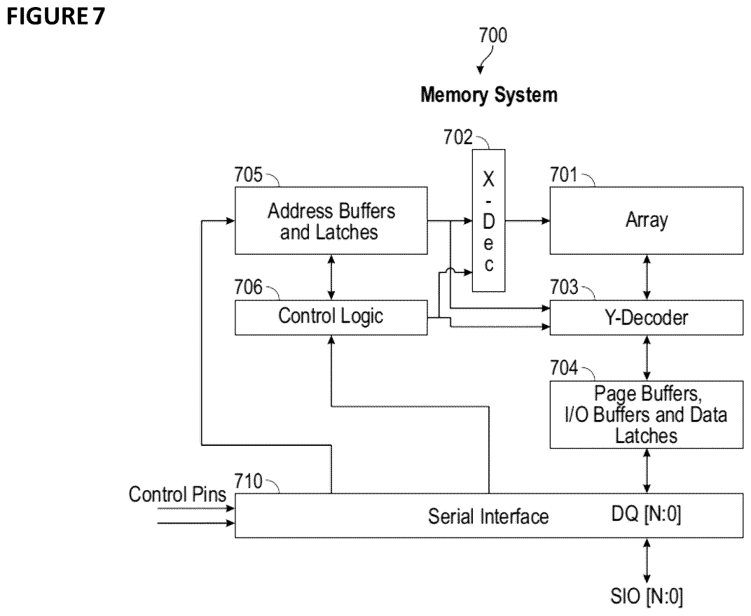

FIG. 7 depicts system 700 comprising serial interface 710 that can be used as an interface for system 600. Serial interface 710 can be a legacy serial interface such as those known as QSPI (Quad SPI) and OSPI (Octal SPI), or a modified version thereof configured to provide a wider I/O interface with higher transfer bandwidth as described below in Table No. 11. System 700 comprises array 701; row decoder 702; column decoder 703; page buffers, I/O buffers, and data latches 704; address buffers and latches 705; and control logic 706. Serial interface 710 comprises multiple signal lines and pins (which might comprise pins, balls, wires, electrical traces, or other electrical paths) to carry address signals, I/O signals (which include data input signals and data output signals in a time-multiplexed manner), and control signals. A version of serial interface 710 using or based on the QSPI legacy serial interface can include control pins carrying signals CE #(chip enable), WP #(write protect), HOLD #(hold), SCK (clock) and 4 lines for I/O signals [3:0]. A version of serial interface 710 using or based on the OSPI legacy serial interface can include control signals CE #(chip enable), WP #(write protect), HOLD #(hold), RESET #(reset), INT #(interrupt), DQS (data strobe), SCK (clock) and 8 lines for I/O signals [7:0].

Table No. 5 contains line count information for various versions of serial interface 710 (listed as serial interfaces 710a, 710b, and 710c) and for various versions of a legacy QSPI serial interface.

TABLE NO. 5
LINE COUNT FOR SERIAL INTERFACES

| | Capacity | Control | SIO | Total |
|---|---|---|---|---|
| | Mbit | Lines | Lines | Lines |
| Legacy | 64 | 7 | 4 | 11 |
| Interface | | | | |
| Legacy | 128 | 7 | 4 | 11 |
| Interface | | | | |
| Legacy | 256 | 7 | 4 | 11 |
| Interface | | | | |
| Serial | 64 | 7 | 32 | 39 |
| Interface 710a | | | | |
| Serial | 128 | 7 | 64 | 71 |
| Interface 710b | | | | |
| Serial | 256 | 7 | 128 | 135 |
| Interface 710c | | | | |

In Table No. 5, the Capacity column refers to the storage capacity of array 5701; the Control Lines column refers to the number of control lines (such as CE #, OE #, and WE #); SIO Lines refers to the total number of serial IO lines; and the Total Lines column refers to the sum of the Control Lines and SIO Lines, meaning the sum of the previous two columns. Power supply lines are not included in the total lines value. Serial interfaces 710a, 710b, and 710c use a larger number of total lines than the legacy interfaces discussed in Table No. 9 but can perform I/O bandwidth operations faster than the legacy interface since they have more lines for serial I/O output operations. Other SIO lines such as 8 or 16 are possible.

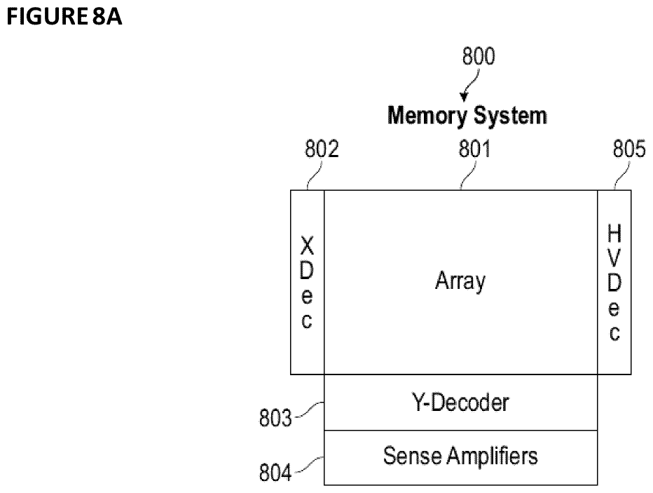

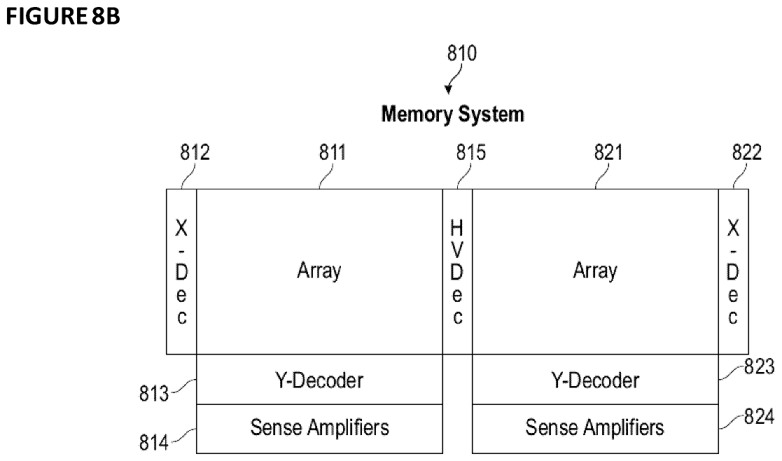

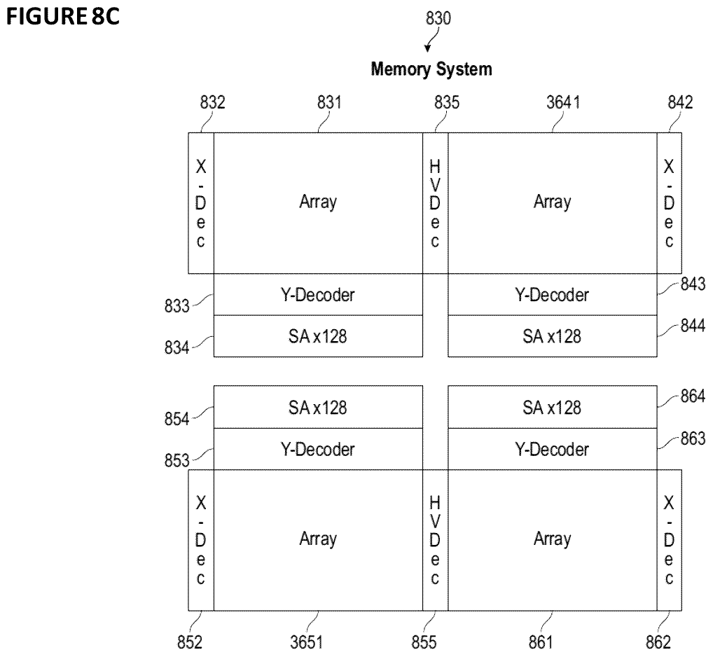

FIGS. 8A, 8B, and 8C depict various system configurations that can utilize serial interface 710 described previously with reference to FIG. 7.

FIG. 8A depicts system 800, which comprises array 801, row decoder 802, column decoder 803, sense amplifiers 804, and high voltage decoder 805.

FIG. 8B depicts system 810, which comprises arrays 811 and 821, row decoders 812 and 822, column decoders 813 and 823, sense amplifiers 814 and 824, and shared high voltage decoder 815.

FIG. 8C depicts system 830, which comprises arrays 831, 841, 851, and 861; row decoders 832, 842, 852, and 862; column decoders 833, 843, 853, and 863; sense amplifiers 834, 844, 854, and 864; and shared high voltage decoders 835 and 855.

Table No. 6 contains line count and sense amplifier count information for systems 800, 810, and 830 compared to comparable legacy systems.

TABLE NO. 6
LINE COUNT AND SENSE AMPLIFIER
COUNT FOR SYSTEMS

| | Capacity | SIO | Sense | IO WIDTH |
|---|---|---|---|---|
| | Mbit | Lines | Amplifiers | FOR PAGE |
| Legacy | 64 | 4 | 16 | 128 |
| OSPI System | | | | |
| Legacy | 128 | 8 | 32 | 128 |
| OSPI System | | | | |
| System 800 | 64 | 32 | 128 | 128 |
| System 810 | 128 | 64 | 256 | 128 |
| System 830 | 256 | 128 | 512 | 128 |

In Table No. 6, the Capacity column refers to the storage capacity of the arrays; the SIO Lines column refers to the number of serial IO lines; the Sense Amplifiers column refers to the number of sense amplifiers; the IO Width For Page column refers to the IO width that is used for a page of data, where a page typically comprises data in two or more rows of memory cells. Systems 800, 810, and 830 can perform I/O operations faster than the legacy OSPI systems since they have more lines for serial I/O output operations.

FIG. 9 depicts an example of a memory system 900. Memory system 900 can comprise voltage regulator (such as a LDO regulator, low-dropout voltage regulator) 902, serial interface 904, memory system 906 (e.g., which may be system 600 or system 700 without the interface 710 block and/or support circuitry, or similar), and output circuit 908. Voltage regulator 902 can include a low-dropout regulator (LDO) and/or other components and may be configured to receive VddIO as a relatively high voltage input and provide Vddcore_int as a lower voltage output for use by memory system 906 and/or the serial interface 904. As an illustrative example, VddIO may be 3.3V and Vddcore_int may be 1.8V. In some embodiments, the LDO in voltage regulator 902 may be separate from any other LDO used by any component of memory system 900 (e.g., within system 600). Serial interface 904 can be QSPI, OSPI, or other designs such as those described above. Memory 906 can include at least one system 600. The I/O signals from serial interface 904 to memory 906 can include address signals (Addr), data in (DINx), and/or control signals. Memory 906 can provide data out (DOUTx) to output circuit 908.

The examples discussed below may include components and techniques reducing or eliminating current peaks that otherwise could occur within systems 600, 700, and 900 and components thereof during address switching, data switching, bitline precharging for read operations, charge pump generation, and other operations. For example, some examples may include data precharging that can prevent current peaks during data sensing. Some examples may include address bit precharging that can prevent current peaks during addressing. Some examples may include address sequencing with limited bit changes. Some examples may include asymmetrical circuit sensing staggering. Some examples may include asymmetrical load staggering. Some examples may include redundancy repair clustering. Some examples may include power supply generation techniques. Some examples may include a combination of two or more of the above components and techniques. Each of these components and techniques can contribute to reductions in current peaks as described in detail below.

### Precharging

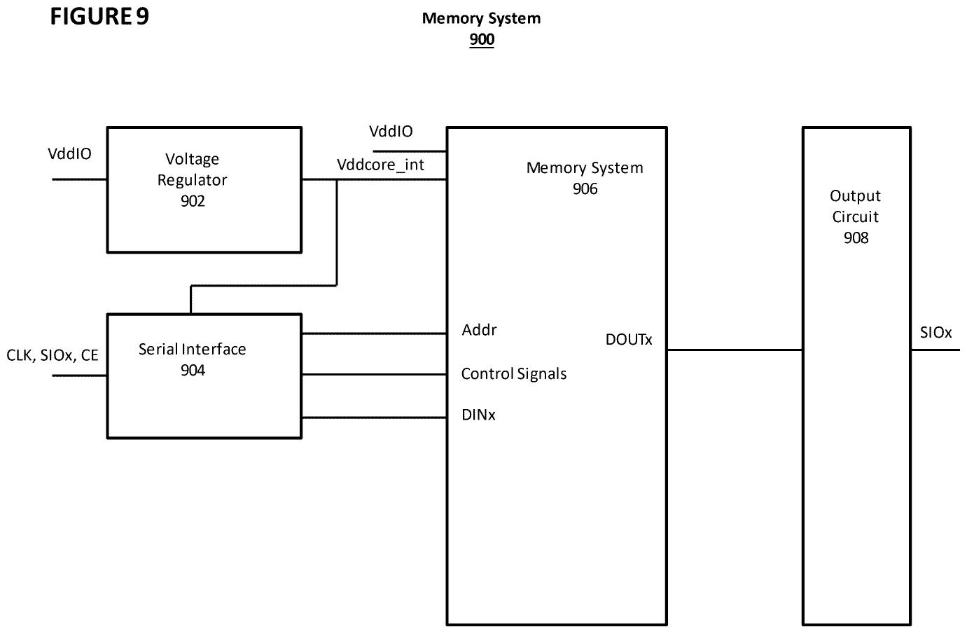

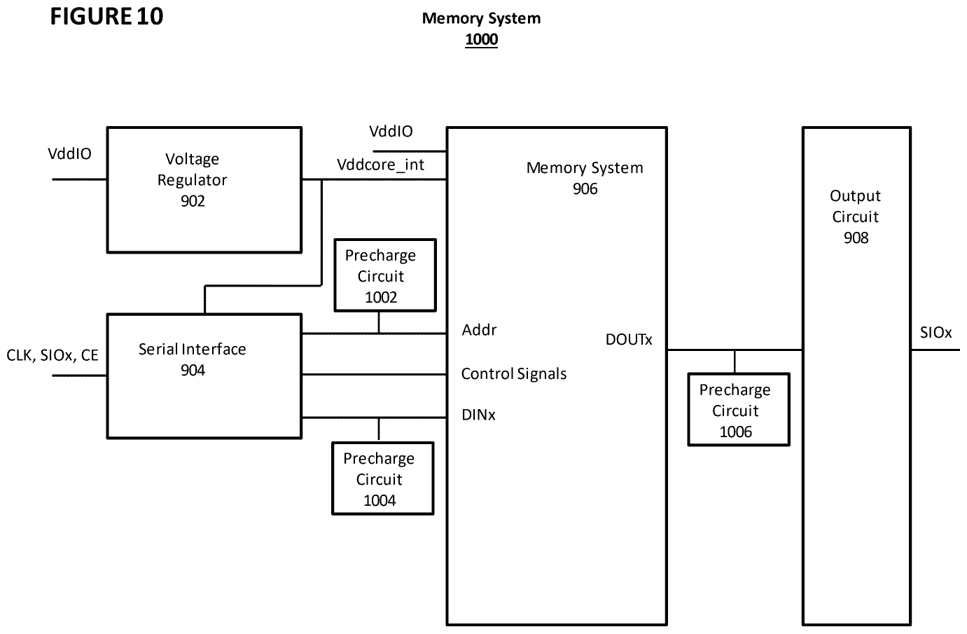

FIG. 10 depicts memory system 1000. Memory system 1000 contains certain components also contained in memory system 900 in FIG. 9, such as voltage regulator 902, serial interface 904, memory system 906, and output circuit 908, and those components operate in the same manner described above with respect to FIG. 9. Memory system 1000 also comprises precharge circuit 1002, precharge circuit 1004, and precharge circuit 1006.

To reduce or eliminate current peaks found in prior art memory systems, before a read, program, or erase operation of memory system 906, precharge circuit 1002 charges address lines (Addr) to a predetermined positive voltage such as Vddcore_int, precharge circuit 1004 and charges data lines (DINx) to a predetermined positive voltage such as Vddcore_int, and precharge circuit 1006 charges data output lines (DOUTx) to a predetermined positive voltage such as Vddcore_int. As a result, during the read, program, or erase operation, each of the address lines, data lines, and data output lines will undergo a smaller increase in voltage, or perhaps none at all, if the line receives a “1,” as the voltage of the line will increase from the predetermined positive voltage of the precharge operation to the voltage of the “1” value. If the predetermined positive voltage of the precharge operation is the same as the voltage of the “1” value, then there will be no increase in voltage of the line. As a result, the current peak that is present in prior art systems will be reduced or eliminated. If the line instead receives a “0,” then the line will be discharged from the predetermined positive voltage of the precharge operation to the voltage of a “0” value (which could be ground or another voltage different than the voltage of a “1” value).

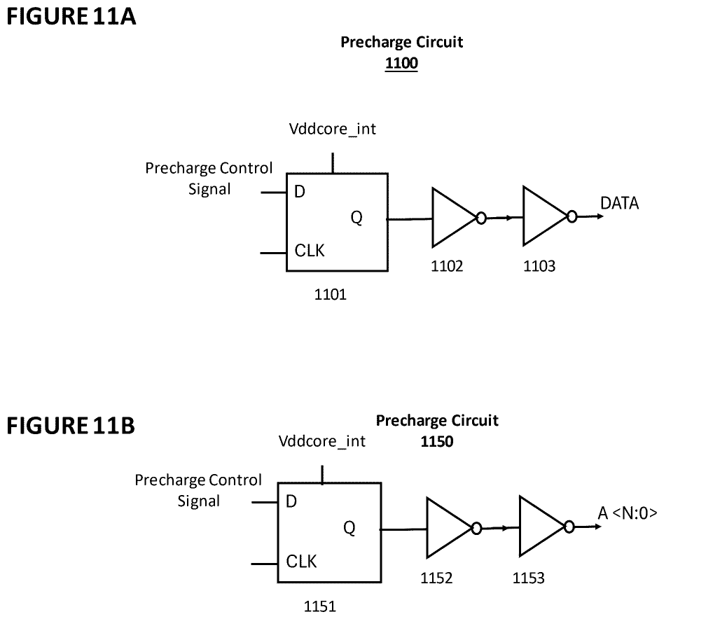

FIG. 11A depicts precharge circuit 1100, which is example instantiation of precharge circuit 1002 and precharge circuit 1006 in FIG. 10. Precharge circuit 1100 comprises latch 1101, inverter 1102, and inverter 1103. Latch 1101 receives a precharge control signal on its D input and a clock on its CLK input. The precharge control signal goes high at the beginning of the precharge operation (where the output, Q, will go high on a rising clock edge and then be held at that level) and goes low at the end of the precharge operation (where the output, Q, will go low on a rising clock edge and then be held at that level). Inverters 1102 and 1103 propagate the output, Q, as DATA and act as a voltage buffer.

FIG. 11B depicts precharge circuit 1150, which is example instantiation of precharge circuit 1004 in FIG. 10. Precharge circuit 1150 comprises latch 1151, inverter 1152, and inverter 1153. Latch 1151 receives a precharge control signal on its D input and a clock on its CLK input. The precharge control signal goes high at the beginning of the precharge operation (where the output, Q, will go high on a rising clock edge and then be held at that level) and goes low at the end of the precharge operation (where the output, Q, will go low on a rising clock edge and then be held at that level). Inverters 1152 and 1154 propagate the output, Q, as A <N: 0> and act as a voltage buffer.

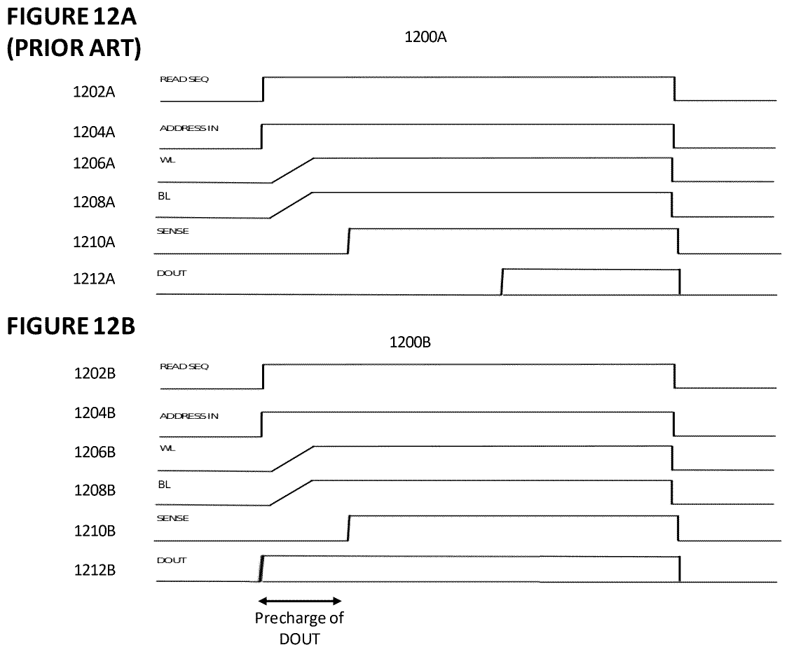

FIG. 12A depicts timing diagram 1200A for a prior art system without precharge circuits. Here, the I/O line in question is DOUT 1210A, although it should be understood that this example applies similarly to DIN and/or Addr. In the prior approach, memory system 900 receives read enable command 1202A and address 1204A. A word line (WL) 1206A and bit line (BL) 1208A of the received address are charged shortly thereafter. The sense command 1210A can cause memory 906 to output DOUT 1212A. Here, the value of DOUT 1212A is 1, so DOUT 1212A goes high in response to sense command 1210A. This can cause a current spike.

FIG. 12B depicts timing diagram 1200B for system 1000, which includes precharge circuits. System 1000 receives read enable command 1202B and address 1204B as in the prior approach. WL 1206B and BL 1208B of the received address are charged shortly thereafter. The sense command 1210B can cause memory system 906 to output DOUT 1212B. Here, the value of DOUT 1212B is 1, but DOUT 1212B is precharged high before the sense command 1210B is received, and remains high in response to the sense command 1210B. This can reduce or avoid current spikes present in the prior art. Precharging may be used alone or in combination with the other current spike reduction and elimination techniques described herein.

### Asymmetrical Staggering and Symmetrical Staggering

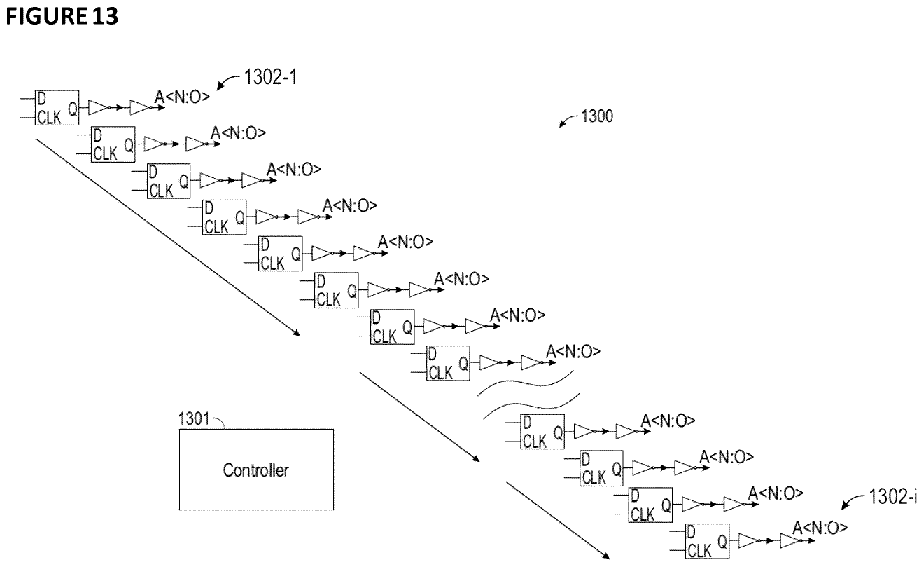

In some embodiments, one or more operations of memory system 900 can be staggered to reduce current spikes. For example, precharging, sensing, addressing, reading, writing, erasing, and/or other operations can be staggered. FIG. 13 depicts an example of controller 1301 implementing circuit staggering 1300 for a system. Controller 1301 groups address inputs so that respective groups of precharging voltage or other data are sent sequentially, as opposed to sending all signals at once. The number of lines (e.g., address lines or data lines) in each group can be symmetrical, where each group has the same number of lines, or asymmetrical, where the number of lines varies among groups.

In the example shown in FIG. 13, group 1302-1 contains 8 lines and group 1302-i contains 4 lines. Between group 1302-1 and group 1302-i, intermediate sized group(s) may be formed (e.g., a 7, 6, and/or 5 bit group). These group sizes are examples only, and in practice, any group sizes may be used. Controller 1301 can cause an address buffer (e.g., address buffer 705 described above) to provide a first group to the array (e.g., array 701 described above) first, and insert progressively increasing delays for each subsequent group so that the array receives the address groups staggered in time.

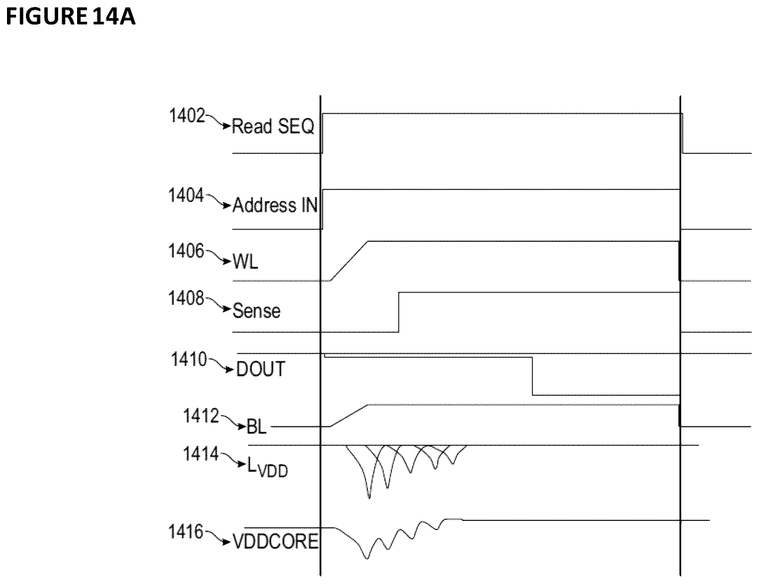

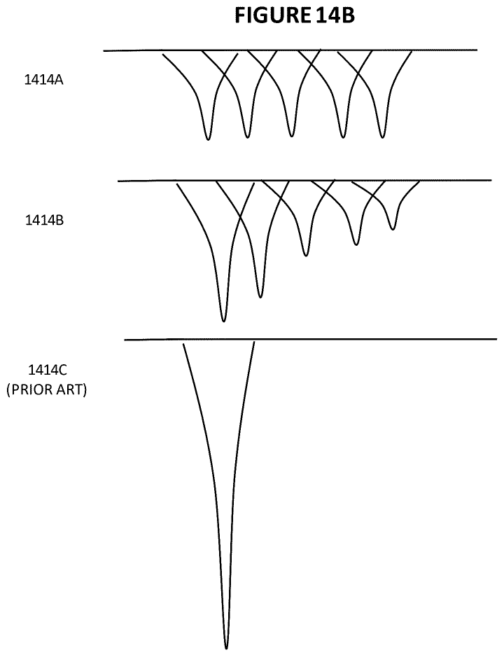

FIG. 14A depicts an example timing diagram 1400 for a system with asymmetrical circuit staggering, illustrating the effect of the staggering on current spiking. For example, memory system 900 receives read enable command 1402 and address 1404. WL 1406 and BL 1412 of the received address are charged shortly thereafter, but this is done by asymmetrical circuit staggering. The circuit staggering is done for the selected bitline pre-charging for sensing in this example. In practice, charging can be performed at times such as the beginning of a read cycle (as shown), initial settling time, setup time, and/or other times when active memory operations are not in progress. The sense command 1408 can cause memory 906 to output DOUT 1410.

In the example timing diagram 1400, LVDD 1414 shows current spikes in source VDD, and VDDCORE 1416 shows spikes in the regulated output of voltage regulator 902. As shown, current spikes occur, but they are spaced out in time and progressively decreasing. As a result of the temporal spacing, large-scale current spikes are avoided. Moreover, as a result of the progressive decrease due to the progressively smaller groups 1202 provided by the address buffer, current draw decreases as other activities of memory system 900 begin to draw current. For example, as noted above, the sense command 1408 can draw current.

FIG. 14B depicts current spikes generated in LVDD by a system with symmetrical staggering in timing diagram 1414A, asymmetrical staggering in timing diagram 1414B, and no staggering in timing diagram 1414C. Clearly, asymmetrical staggering and symmetrical staggering both reduce a magnitude of the current spike at the cost of extending the current spike(s) over a longer period of time. It can also be appreciated that the asymmetrical staggering allows the current to fall to a lower level more quickly than the symmetrical staggering.

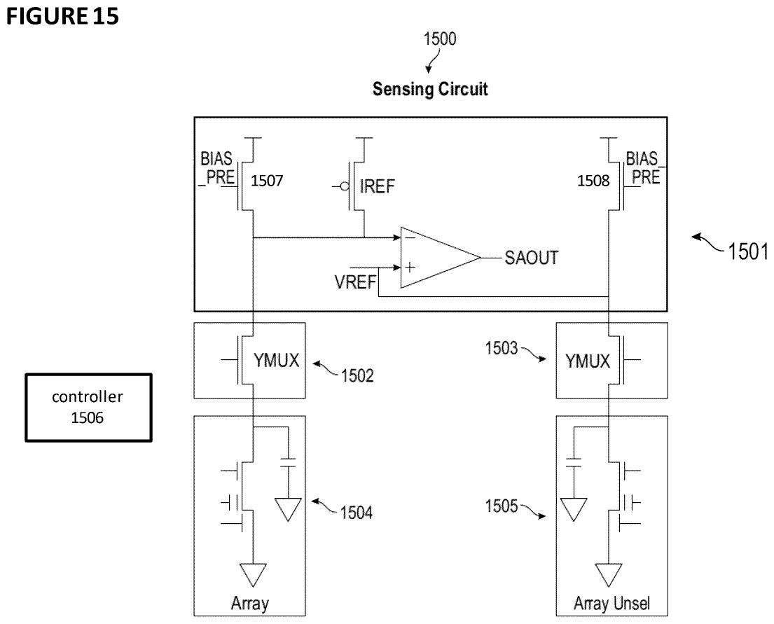

FIG. 15 shows an example sensing circuit 1500 operable according to the timing of FIGS. 14A and 14B and/or similar timing schemes. Sensing circuit 1500 comprises sense amplifier 1501, a portion 1502 of a column multiplexor, a portion 1503 of a column multiplexor, selected memory cell 1504, and reference memory cell 1505. Sensing circuit 1500 is controlled by controller 1506. When a read operation of selected memory cell 1504 is desired, controller 1506 will cause control signals BIAS_PRE to go high and transistors 1507 and 1508 will be turned on to precharge the bit lines for selected memory cell 1504 and reference memory cell 1505. Portions 1502 and 1503 of the column multiplexor are asserted when a column address (not shown) is received by the larger column multiplexor and the column address corresponds to the column of selected memory cell 1504, in which case portions 1502 and 1503 will be asserted such that a read operation of selected memory cell 1504 can occur. Optionally, controller 1506 can block or enable such operations to implement a staggering operation. A memory system (e.g., system 900) or a sensing block thereof may include a plurality of sensing circuits 1500 such that every memory cell in the array is coupled to an instantiation of transistor 1502 and every reference memory cell is coupled to an instantiation of transistor 1503. Controller 1506 can turn on one or more of instantiations of transistors 1502, 1503, 1504, and 1505 to precharge their respective bitlines in a staggered sequence, either symmetrically (where the bitlines are precharged in groups, with each group containing the same number of bitlines) or asymmetrically (where the bitlines are precharged in groups, with the groups containing varying numbers of bitlines).

When all necessary bitlines are precharged, the instantiations of sense amplifier 1501 may sense bit values for precharged cells and provide an output at SAOUT.

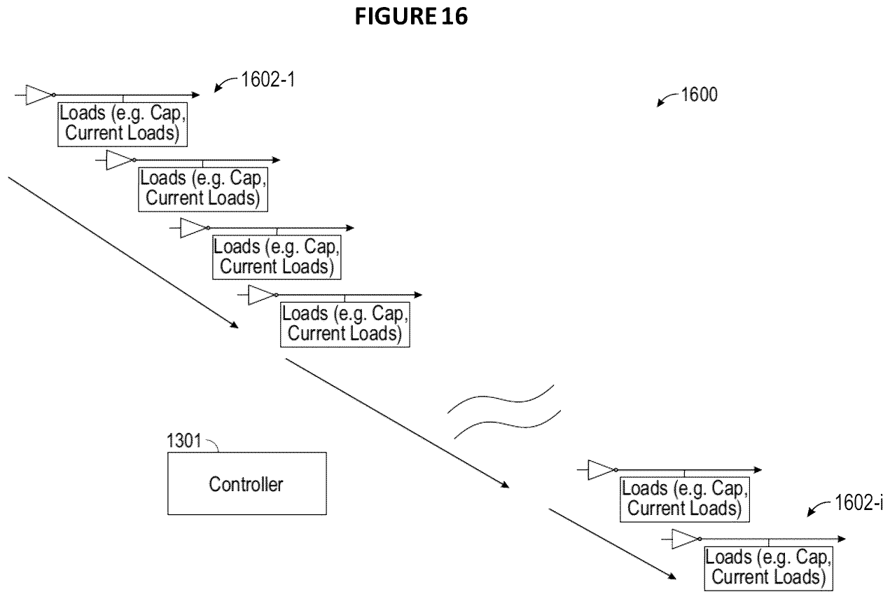

Asymmetrical or symmetrical staggering may be applied to other operations of memory system 900. FIG. 16 depicts an example of controller 1301 (previously discussed with reference to FIG. 13) implementing load staggering 1600 for a system. Here, memory system 900 control can account for loads external to the array that can cause current to spike, such as capacitive and/or current loads in circuitry receiving DOUT from memory system 900. To reduce magnitude of the current spike at the cost of extending duration, the system can stagger any operation, such as a read operation, as with the addressing example above. For example, group 1602-1 includes 5 lines, and group 1602-i includes 2 lines Between group 1602-1 and group 1602-i, intermediate sized group(s) may be formed (e.g., a 4 and/or a 3 line group). These group sizes are examples only, and in practice, any group sizes may be used. An output circuit (e.g., output circuit 607 as described above) can output a first group and insert progressively increasing delays for each subsequent group so that the outputs are staggered in time. Staggering, whether symmetrical or asymmetrical or both, may be used alone or in combination with the other current spike reduction and/or elimination techniques described herein.

### Address Sequencing

Another feature that can reduce current spikes is optimization of address sequencing. When an address code changes, one or more bits change. Each bit change can draw current, and when multiple bits change at the same time, more current is drawn, which can lead to current spikes. For example, Table No. 7 below shows a binary address sequence for 16 decimal values represented by four bits in an array. In some cases, such as a change from a 15 to a 0 or from a 7 to an 8, four bits can change simultaneously.

TABLE NO. 7
BINARY ADDRESS SEQUENCE

| DEC | A3 | A2 | A1 | A0 |
|---|---|---|---|---|
| 0 | 0 | 0 | 0 | 0 |
| 1 | 0 | 0 | 0 | 1 |
| 2 | 0 | 0 | 1 | 0 |
| 3 | 0 | 0 | 1 | 1 |
| 4 | 0 | 1 | 0 | 0 |
| 5 | 0 | 1 | 0 | 1 |
| 6 | 0 | 1 | 1 | 0 |
| 7 | 0 | 1 | 1 | 1 |
| 8 | 1 | 0 | 0 | 0 |
| 9 | 1 | 0 | 0 | 1 |
| 10 | 1 | 0 | 1 | 0 |
| 11 | 1 | 0 | 1 | 1 |
| 12 | 1 | 1 | 0 | 0 |
| 13 | 1 | 1 | 0 | 1 |
| 14 | 1 | 1 | 1 | 0 |
| 15 | 1 | 1 | 1 | 1 |

Some embodiments may encode addressing using a Gray code, wherein binary numerals are arranged so that each successive value differs from the previous value by only one bit. Table No. 8 below shows the same addressing as Table No. 11 encoded using a Gray code. By addressing memory 906 using Gray code, memory system 900 can reduce current spikes.

TABLE NO. 8
ONE-BIT GRAY CODE ADDRESS SEQUENCE

| DEC | A3 | A2 | A1 | A0 |
|---|---|---|---|---|
| 0 | 0 | 0 | 0 | 0 |
| 1 | 0 | 0 | 0 | 1 |
| 2 | 0 | 0 | 1 | 1 |
| 3 | 0 | 0 | 1 | 0 |
| 4 | 0 | 1 | 1 | 0 |
| 5 | 0 | 1 | 1 | 1 |
| 6 | 0 | 1 | 0 | 1 |
| 7 | 0 | 1 | 0 | 0 |
| 8 | 1 | 1 | 0 | 0 |
| 9 | 1 | 1 | 0 | 1 |
| 10 | 1 | 1 | 1 | 1 |
| 11 | 1 | 1 | 1 | 0 |
| 12 | 1 | 0 | 1 | 0 |
| 13 | 1 | 0 | 1 | 1 |
| 14 | 1 | 0 | 0 | 1 |
| 15 | 1 | 0 | 0 | 0 |

The Gray code where sequential values differ by one bit is one example of addressing that reduces current spikes, but other embodiments may be possible. For example, as discussed above, a four-bit address can experience four-bit address changes, and any encoding that reduces a maximum number of bits in an address change can reduce current spikes. The Gray code for addressing, or any other addressing scheme that reduces a number of possible bit changes below a maximum number physically possible for a number of address registers, may be used alone or in combination with the other current spike reduction and/or elimination techniques described herein.

### Redundancy Repair Clustering

In some embodiments, memory system 900 may include redundancy repair features (e.g., redundancy controller circuitry or the like) configured to map bad storage cells to addresses for good storage cells, so that the bad storage cells are no longer used during normal operation. To perform redundancy repair, memory system 900 can compare incoming addresses with stored bad addresses to determine if addressed storage cells needs to be replaced. Comparison and determination may be in real time as addressing occurs. However, such comparison and determination can cause current spikes as incoming addresses are compared with large numbers of possible addresses. For example, assume 1 row is being read per 1 Mb memory array, and there are 128 redundancy repairs made for a 128 Mb array. In this example, an incoming address must be compared with 128 bad addresses, causing a large current spike.

To mitigate such current spikes, some embodiments may cluster redundancy repair processing. Redundancy repair clustering may provide asymmetrical comparison where the incoming address is compared against smaller subsets of the available bad addresses sequentially until a match is found or until all addresses are checked. This technique can reduce a current spike at the expense of additional gate delays.

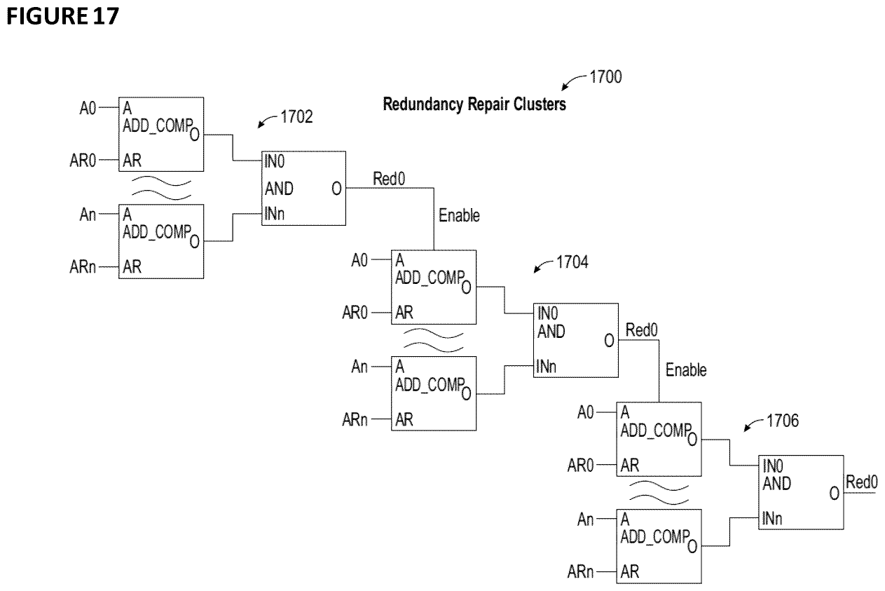

FIG. 17 depicts an example set of redundancy repair clusters 1700 including three clusters 1702, 1704, 1706. Each cluster 1702, 1704, 1706 in this example can receive four address bits. Accordingly, set 1700 can process 12 redundancy repair addresses. The set 1700 may process address bits as follows. First cluster 1702 may compare four incoming address bits against like redundancy repair address bits and, if there is a true comparison result, enable comparison operation of second cluster 1704. If the comparison yields a false result, no further comparisons may be necessary. In the case where second cluster 1704 is enabled, second cluster 1704 may compare four incoming address bits against like redundancy repair address bits and, if there is a true comparison result, enable third cluster 1706. If the comparison yields a false result, no further comparisons may be necessary. In the case where third cluster 1706 is enabled, third cluster 1706 may compare four incoming address bits against like redundancy repair address bits and, if there is a true comparison result, this can indicate the incoming address matches a bad storage cell and should be rerouted. By performing three sequential comparisons instead of one, current spike magnitude may be reduced by ⅓ at the expense of an additional six gate delay.

While FIG. 17 shows an example having three clusters 1702, 1704, 1706 each handling four respective bits, it should be understood that redundancy repair clustering is scalable in terms of cluster count and/or bits per cluster. Any clustering into plural sequential comparison operations can reduce current spikes. Redundancy repair clustering may be used alone or in combination with the other current spike reduction and/or elimination techniques described herein.

As used herein, the terms “over” and “on” both inclusively include “directly on” (no intermediate materials, elements or space disposed therebetween) and “indirectly on” (intermediate materials, elements or space disposed therebetween). Likewise, the term “adjacent” includes “directly adjacent” (no intermediate materials, elements or space disposed therebetween) and “indirectly adjacent” (intermediate materials, elements or space disposed there between), “mounted to” includes “directly mounted to” (no intermediate materials, elements or space disposed there between) and “indirectly mounted to” (intermediate materials, elements or spaced disposed there between), and “electrically coupled” includes “directly electrically coupled to” (no intermediate materials or elements there between that electrically connect the elements together) and “indirectly electrically coupled to” (intermediate materials or elements there between that electrically connect the elements together). For example, forming an element “over a substrate” can include forming the element directly on the substrate with no intermediate materials/elements therebetween, as well as forming the element indirectly on the substrate with one or more intermediate materials/elements there between.

What is claimed is:

1. A method comprising:
precharging at least one input to or output from a memory array to a supply voltage;
performing at least one operation by the memory array requiring the precharged at least one input to or output from the memory array to have a voltage lower than the supply voltage; and
discharging the precharged at least one input to or output from the memory array to the voltage lower than the supply voltage in response to the at least one operation.

2. The method of claim 1, wherein at least one input to or output from the memory array is a data input, a data output, or an address bit.

3. The method of claim 1, wherein the supply voltage is a regulated voltage from a regulator isolated from the memory array.

4. The method of claim 1, wherein the voltage lower than the supply voltage is ground.

5. The method of claim 1, wherein the precharging is before the performing.

6. The method of claim 1, wherein the precharging comprises sequentially precharging groups of multiple inputs or outputs.

7. The method of claim 6, wherein the groups are asymmetrical in size.

8. A method comprising:
performing an operation on a memory array, wherein the operation is performed by:
sending first signals to a first plurality of inputs to or outputs from the memory array forming a first group, and
after sending the first signals, sending second signals to a second plurality of inputs to or outputs from the memory array forming a second group different from the first group;
wherein each of the first signals and second signals are required to complete the operation.

9. The method of claim 8, wherein the first plurality of inputs to or outputs from the memory array has a higher count than the second plurality of inputs to or outputs from the memory array.

10. The method of claim 8, wherein the operation comprises:
precharging the first group and the second group to a supply voltage;
performing at least one functional operation by the memory array requiring at least one of the precharged inputs to or outputs from the memory array to have a voltage lower than the supply voltage; and
discharging the at least one of the precharged inputs to or outputs from the memory array to the voltage lower than the supply voltage in response to the at least one operation.

11. The method of claim 10, wherein the voltage lower than the supply voltage is ground.

12. The method of claim 1, wherein the first plurality of inputs to or outputs from the memory array and the second plurality of inputs to or outputs from the memory array are data inputs, data outputs, or address bits.

13. A system comprising:
an array comprising non-volatile memory cells arranged into rows and columns; and
an addressing block to address the rows and columns by a binary address sequence having all addresses differ from adjacent addresses in the sequence by fewer than a maximum number of binary bits in the addresses.

14. The system of claim 13, wherein the binary address sequence is a Gray code.

15. A method comprising:
comparing, by a first address cluster, a first subset of a plurality of address bits with at least one known bad address of a memory array;
in response to a true result of the comparing by the first address cluster, comparing, by a second address cluster, a second subset of the plurality of address bits with the at least one known bad address of the memory array;
in response to a true result of the comparing by the second address cluster, storing incoming data in an address of the memory array other than the at least one known bad address.

16. A system comprising:
an array of non-volatile memory cells arranged in rows and columns; and
a cluster comparison circuit comprising a plurality of address clusters each configured to compare a respective subset of address bits against a respective portion of at least one known bad address of the memory array;
wherein in response to each of the plurality of address clusters returning a true result, the array is configured to address the non-volatile memory cells at an address different from an address indicated by the address bits.

17. A method comprising:
performing a staggered precharging of a plurality of data lines for a plurality of memory cells, the staggered precharging comprising:
precharging a first group of the data lines at a first time, and
precharging a second group of the data lines at a second time after the first time; and
sensing data stored in the plurality of memory cells having the precharged data lines.

18. The method of claim 17, wherein the plurality of data lines comprise a plurality of bit lines.

19. The method of claim 17, wherein the second group of the data lines is smaller than the first group of the data lines.

20. The method of claim 17, wherein the staggered precharging further comprises precharging at least one additional group of data lines at least one time subsequent to the second time, wherein the at least one additional group of the data lines is smaller than at least one of the first group of the data lines and the second group of the data lines.

21. A system comprising:
an array of non-volatile memory cells arranged in rows and columns;
a plurality of sensing circuits, wherein each of the columns of memory cells in the array is coupled to one of the plurality of sensing circuits; and
a controller for pre-charging the plurality of sensing circuits in a staggered sequence.

22. The system of claim 21, wherein the staggered sequence is symmetrical.

23. The system of claim 21, wherein the staggered sequence is asymmetrical.
